(19) United States
(12) Patent Application Publication
(10) Pub. No.: US 2002/0137358 A1
(43) Pub. Date: Sep. 26, 2002

(54) Multiple point support assembly for a stage

(76) Inventors: Mike Binnard, Belmont, CA (US); Kazuya Ono, San Carlos, CA (US); Bausan Yuan, San Jose, CA (US); Martin E. Lee, Saratoga, CA (US)

Correspondence Address: STEVEN G. ROEDER, THE LAW OFFICE OF STEVEN G. ROEDER, 5560 Chelsea Avenue, La Jolla, CA, 92037, US

(21) Appl. No.: 09/779,944

(22) Filed: Feb. 8, 2001

(51) Int. Cl. B32B 17/00; B32B 18/00; G01K 1/08; H01J 3/26; H01L 21/469; H01J 3/14

(52) U.S. Cl. 438/758; 428/210; 250/398

(57) ABSTRACT

A device stage assembly (10) for positioning a device (26) is provided herein. The device stage assembly (10) includes a mover housing (44), a device stage (14), a support assembly (18), and a control system (22). The support assembly (18) moves the device stage (14) relative to the mover housing (44) under the control of the control system (22). Uniquely, the support assembly (18) includes at least four, spaced apart Z device stage movers (84), (86), (88), (90) that move the device stage (14) relative to the mover housing (44). Further, the control system (22) controls the Z device stage movers (84), (86), (88), (90) to inhibit dynamic and static deformation of the device stage (14) during movement of the device stage (14). Further, the four Z device stage movers (84), (86), (88), (90) distribute forces on the device stage (14) in a way that more closely matches the gravitational and inertial loads on the device stage (14).

### FIELD OF THE INVENTION

The present invention is directed to a support assembly for a stage. More specifically, the present invention is directed to a multiple point support assembly for precisely positioning and supporting a device stage and a wafer for an exposure apparatus.

### BACKGROUND

Exposure apparatuses are commonly used to transfer images from a reticle onto a semiconductor wafer during semiconductor processing. A typical exposure apparatus includes an illumination source, a reticle stage assembly that retains a reticle, a lens assembly and a wafer stage assembly that retains a semiconductor wafer. The reticle stage assembly and the wafer stage assembly are supported above a ground with an apparatus frame.

Typically, the wafer stage assembly includes a wafer stage base, a wafer stage that retains the wafer, a guide assembly that guides movement of the wafer stage and a wafer mover assembly that precisely positions the guide assembly, the wafer stage and the wafer. Somewhat similarly, the reticle stage assembly includes a reticle stage base, a reticle stage that retains the reticle, and a reticle mover assembly that precisely positions the reticle stage and the reticle. The size of the images transferred onto the wafer from the reticle is extremely small. Accordingly, the precise relative positioning of the wafer and the reticle is critical to the manufacturing of high density, semiconductor wafers.

Recently, in order to improve the positioning of the wafer, wafer stage assemblies have been developed that include a mover housing and a table mover assembly that moves the wafer stage relative to the mover housing. In these designs, the mover housing moves along the guide assembly. Depending upon the design, the table mover assembly moves the wafer stage relative to the mover housing with at least three degrees of motion. For example, some existing table mover assemblies utilize three spaced apart Z movers to move the wafer stage relative to the mover housing along a Z axis, about an X axis, and about a Y axis. The kinematic arrangement of the Z movers helps to minimize static deformation of the wafer stage.

Unfortunately, movement of the wafer stage with the three Z movers can cause dynamic deformation of the wafer stage. The deformation of the wafer stage influences the position of points on the wafer stage and the wafer. As a result thereof, the deformation can cause an alignment error between the reticle and the wafer. This reduces the accuracy of positioning of the wafer relative to the reticle and degrades the accuracy of the exposure apparatus.

In light of the above, one object of the present invention is to provide a stage assembly that precisely positions a device. Another object is to provide a support assembly that minimizes both static and dynamic deformation of the wafer stage during movement of the wafer stage. Still another object is to provide a stage assembly having improved positioning performance. Yet another object is to provide an exposure apparatus capable of manufacturing precision devices such as high density, semiconductor wafers.

### SUMMARY

The present invention is directed to a device stage assembly for moving a device relative to a mounting base that satisfies these needs. The device stage assembly includes a device stage, a mover housing, a support assembly, and a control system. The device stage retains the device. The support assembly moves the device stage relative to the mover housing under the control of the control system.

Uniquely, as provided herein, the support assembly includes at least four, spaced apart Z device stage movers that move the device stage relative to the mover housing. Further, the control system controls the Z device stage movers to inhibit both dynamic and static deformation of the device stage during movement of the device stage by the Z device stage movers.

The control system controls the support assembly to adjust the position of the device stage along the Z axis, about the X axis and about the Y axis. Preferably, the support assembly includes a first X device stage mover, a second X device stage mover and a Y device stage mover that are controlled by the control system to move the device stage along an X axis, along a Y axis and about a Z axis. With this design, the position of the device stage can be adjusted with six degrees of freedom.

As provided herein, the device stage assembly can include a bending sensor that monitors the bending and deformation of the device stage. The control system controls the Z device stage movers to minimize the bending and deformation measured by the bending sensor.

The device stage assembly can also include a stage mover assembly connected to the mover housing. The stage mover assembly moves the mover housing relative to the mounting base.

Additionally, as provided herein, the device stage assembly also includes a stage base that supports the mover housing and a base support assembly that moves the stage base relative to the mounting base. Preferably, in this design, the base support assembly includes at least four, spaced apart Z base movers that move the stage base relative to the mounting base. Further, the control system controls the Z base movers to inhibit dynamic bending of the stage base during movement of the base stage by the Z base movers.

The device stage assembly is particularly useful in an exposure apparatus. Moreover, the exposure apparatus can include an apparatus frame that supports a portion of the device stage assembly above the mounting base, and a frame support assembly that moves and positions the apparatus frame relative to the mounting base. As provided herein, the frame support assembly can include at least four, spaced apart Z frame movers that move the apparatus frame relative to the mounting base. Further, the control system controls the Z frame movers to inhibit dynamic deformation and bending of the apparatus frame during movement of the apparatus frame by the Z frame movers.

The present invention is also directed to a method for making a stage assembly, a method for making an exposure apparatus, a method for making a device and a method for manufacturing a wafer.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a perspective view of a device stage assembly having features of the present invention;

FIG. 2 is a perspective view of a first embodiment of a device stage and mover housing having features of the present invention;

FIG. 3 is an exploded perspective view of the device stage, and the mover housing of FIG. 2;

FIG. 4 is an exploded perspective view of a second embodiment of the device stage and the mover housing;

FIG. 5 is a perspective view of a pair of attraction type actuators;

FIG. 6A is an illustration of a bottom of a device stage having features of the present invention;

FIG. 6B is a side illustration of a first section of the device stage 14;

FIG. 7 is a schematic illustration of an exposure apparatus having features of the present invention;

FIG. 8A is an exploded perspective view of a base stage assembly having features of the present invention;

FIG. 8B is an exploded perspective view of a portion of a frame stage assembly having features of the present invention;

FIG. 9 is a flow chart that outlines a process for manufacturing a device in accordance with the present invention; and

FIG. 10 is a flow chart that outlines device processing in more detail.

### DESCRIPTION

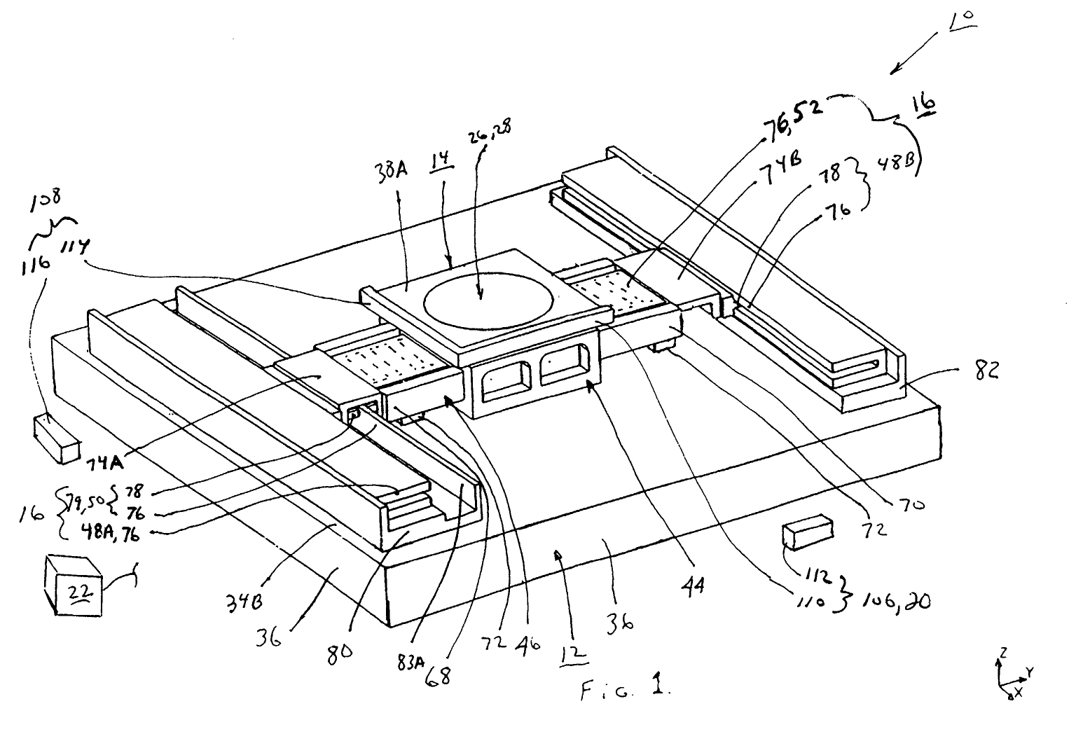

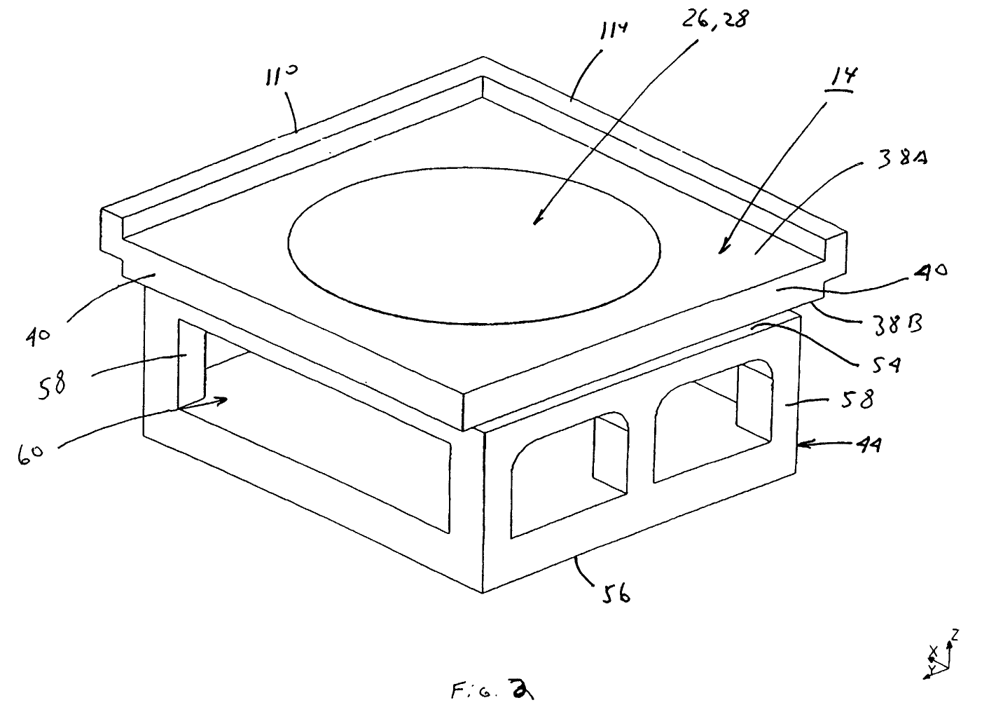

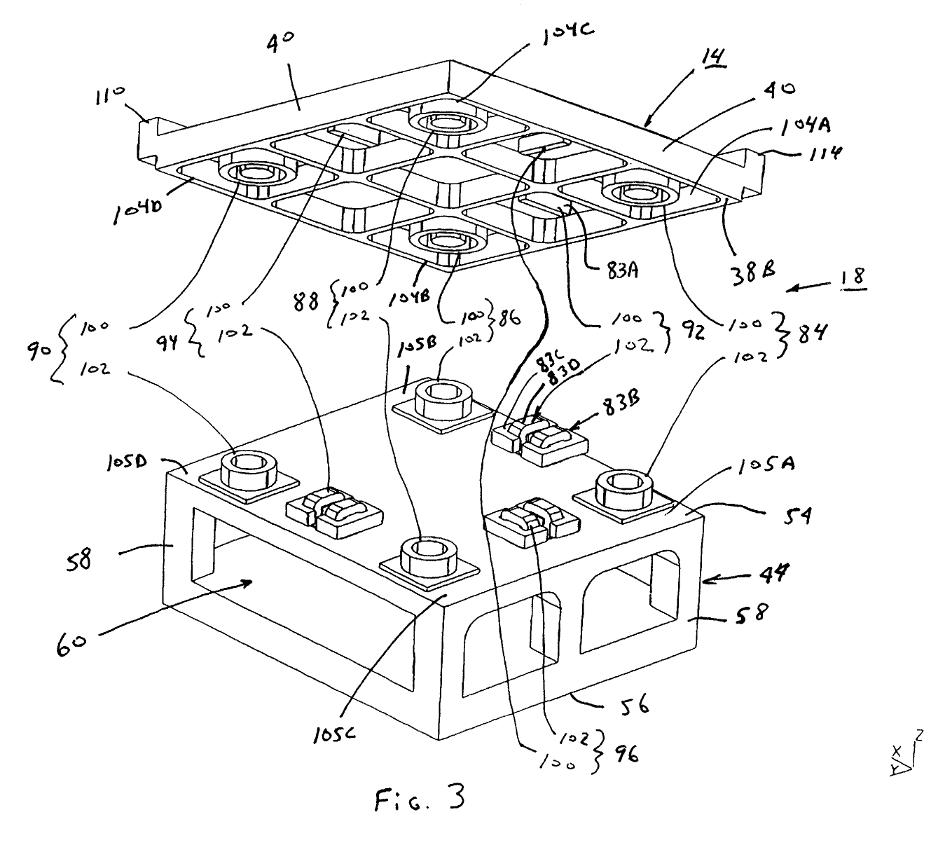

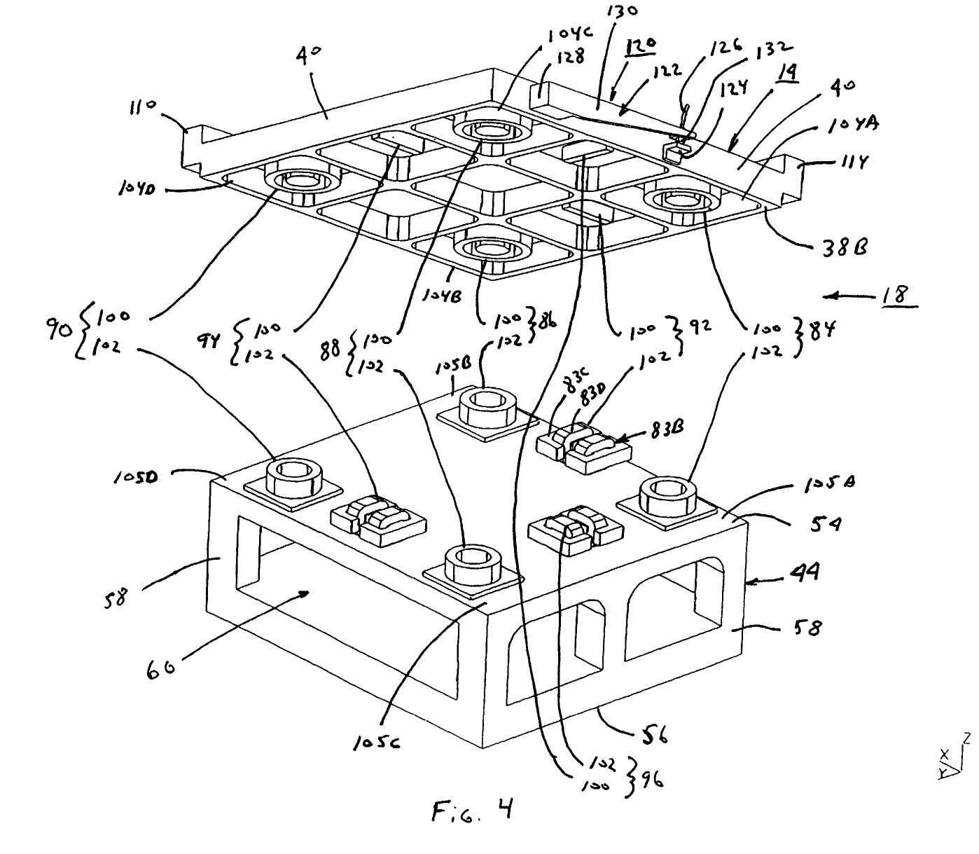

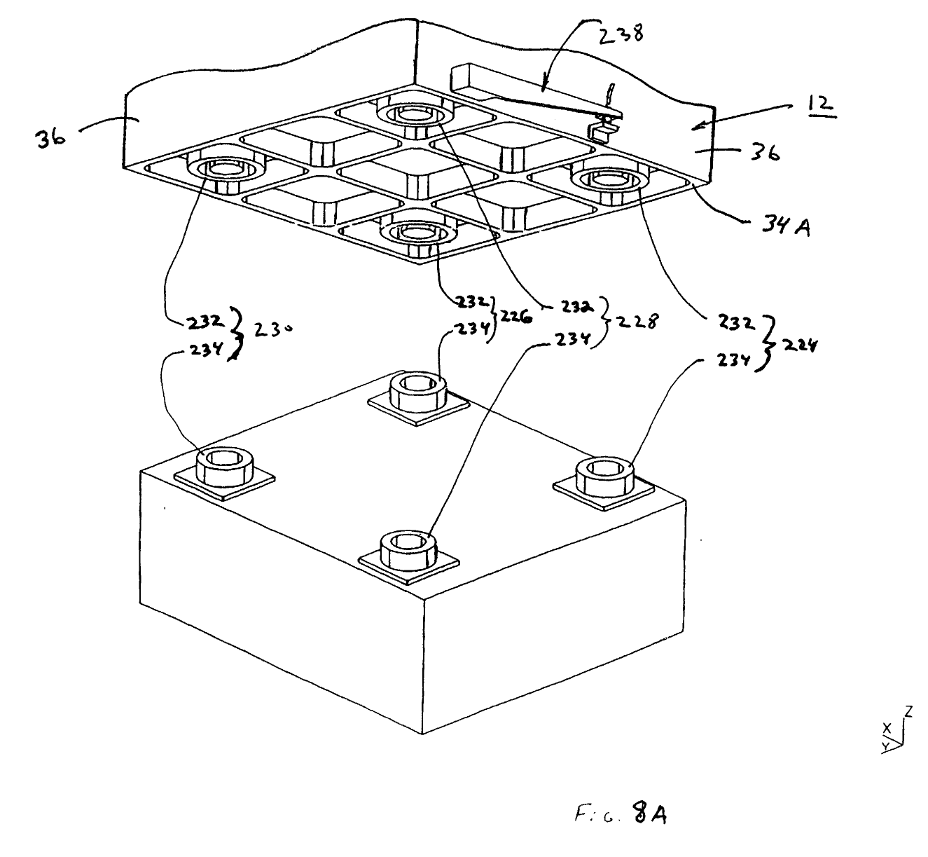

Referring initially to FIGS. 1-4, a device stage assembly 10 having features of the present invention, includes a stage base 12, at least one device stage 14, a stage mover assembly 16, a support assembly 18 (illustrated in FIGS. 3 and 4), a measurement system 20, and a control system 22. The device stage assembly 10 is positioned above a mounting base 24 (illustrated in FIG. 7). As an overview, the support assembly 18 precisely moves and supports the device stage 14 relative to the stage base 12 while minimizing both static and dynamic deformation of the device stage 14. Further, the support assembly 18 distributes forces on the device stage 14 in a way that more closely matches the gravitational and inertial loads on the device stage 14. This improves the accuracy of positioning of the device stage 14.

The device stage assembly 10 is particularly useful for precisely positioning a device 26 during a manufacturing and/or an inspection process. The type of device 26 positioned and moved by the device stage assembly 10 can be varied. For example, the device 26 can be a semiconductor wafer 28 and the device stage assembly 10 can be used as part of an exposure apparatus 30 (illustrated in FIG. 7) for precisely positioning the semiconductor wafer 28 during manufacturing of the semiconductor wafer 28. Alternately, for example, the device stage assembly 10 can be used to move other types of devices during manufacturing and/or inspection, to move a device under an electron microscope (not shown), or to move a device during a precision measurement operation (not shown).

Some of the Figures provided herein include a coordinate system that designates an X axis, a Y axis, and a Z axis. It should be understood that the coordinate system is merely for reference and can be varied. For example, the X axis can be switched with the Y axis and/or the device stage assembly 10 can be rotated.

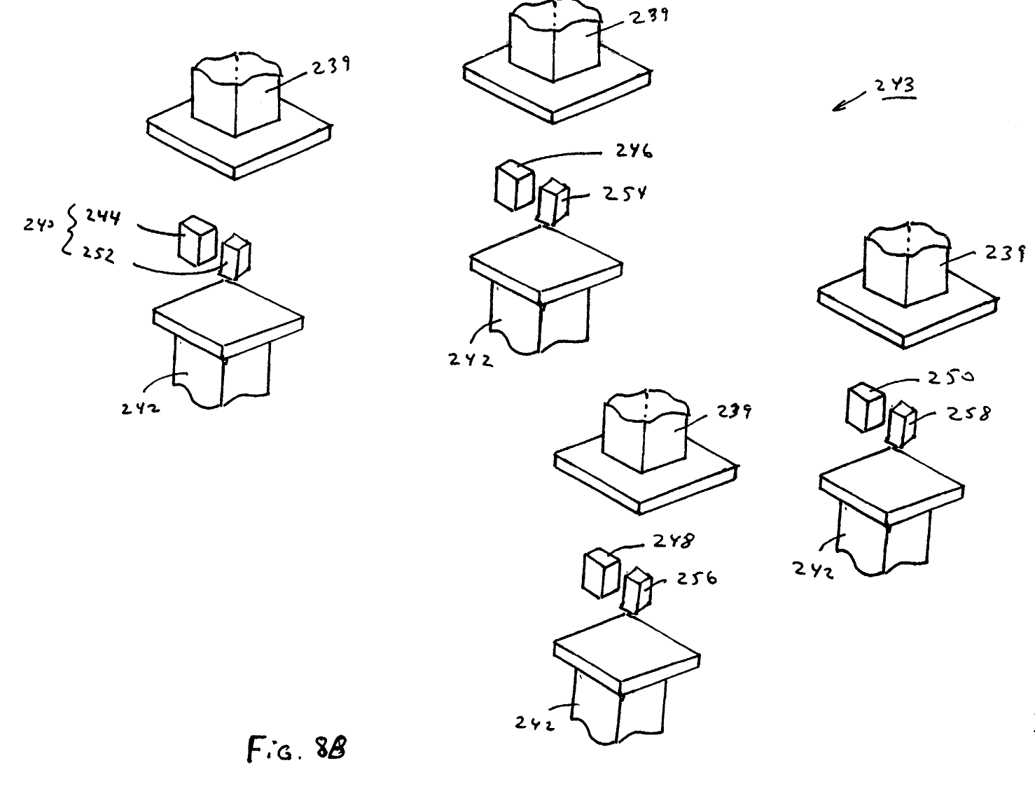

The stage base 12 supports a portion of the device stage assembly 10 above the mounting base 24. The design of the stage base 12 can be varied to suit the design requirements of the device stage assembly 10. In the embodiment illustrated in FIG. 1, the stage base 12 is generally rectangular shaped and includes a base bottom 34A (illustrated in FIG. 8A), a planar base top 34B (sometimes referred to as a guide face), and four base sides 36.

The device stage 14 retains the device 26. The device stage 14 is precisely moved and supported by the support assembly 18 to precisely position the device 26. The design of the device stage 14 can be varied to suit the design requirements of the device stage assembly 10. The device stage 14 illustrated in FIGS. 1-4 is generally rectangular shaped and includes a top 38A, a bottom 38B, and four sides 40.

In the embodiment illustrated in the Figures, the device stage 14 includes a device holder (not shown), a portion of the support assembly 18 and a portion of the measurement system 20. The device holder retains the device 26 during movement. The device holder can be a vacuum chuck, an electrostatic chuck, or some other type of clamp. Alternately, the device stage 14 can include more than one device holders for retaining multiple devices 26.

The stage mover assembly 16 cooperates with the support assembly 18 to move and position the device stage 14 relative to the stage base 12. More specifically, in the embodiments illustrated herein, the stage mover assembly 16 follows the device stage 14 and carries a portion of the support assembly 18 so that the support assembly 18 can position and support the device stage 14.

The design of the stage mover assembly 16 can be varied. In the embodiment illustrated in the Figures, the stage mover assembly 16 includes (i) a mover housing 44, (ii) a guide assembly 46, (iii) a left X guide mover 48A, (iv) a right X guide mover 48B, (v) a Y guide mover 50, and (vi) a Y housing mover 52.

The mover housing 44 is somewhat rectangular tube shaped and includes (i) a generally planar housing top 54, (ii) a housing bottom 56 that is generally parallel with the housing top 54, (iii) a pair of spaced apart housing sides 58 that extend between the housing top 54 and the housing bottom 56, and (iv) a guide opening 60. The guide opening 60 is sized and shaped to receive a portion of the guide assembly 46. In the embodiment illustrated in the Figures, the guide opening 60 is generally rectangular shaped and extends longitudinally along the mover housing 44.

In the embodiments provided herein, the mover housing 44 is maintained above the stage base 12 with a vacuum preload type fluid bearing. More specifically, the housing bottom 56 of the mover housing 44 includes a plurality of spaced apart fluid outlets (not shown), and a plurality of spaced apart fluid inlets (not shown). Pressurized fluid (not shown) is released from the fluid outlets towards the stage base 12 and a vacuum is pulled in the fluid inlets to create a vacuum preload type, fluid bearing between the mover housing 44 and the stage base 12. The vacuum preload type fluid bearing supports the mover housing 44 along the Z axis and allows for motion of the mover housing 44 relative to the stage base 12 along the X axis, along the Y axis and about the Z axis relative to the stage base 12.

Further, the mover housing 44 is maintained apart from the guide assembly 46 with a fluid bearing. More specifically, in this embodiment, pressurized fluid (not shown) is released from fluid outlets (not shown) positioned around the guide opening 60 towards the guide assembly 46 to create a fluid bearing between the mover housing 44 and the guide assembly 46. The fluid bearing allows for motion of the mover housing 44 relative to the guide assembly 46 along the Y axis. Further, the fluid bearing inhibits motion of the mover housing 44 relative to the guide assembly 46 along the X axis and about the Z axis.

Alternately, the mover housing 44 can be supported spaced apart from the stage base 12 and the guide assembly 46 in other ways. For example, a magnetic type bearing (not shown) or a roller bearing type assembly (not shown) could be utilized.

The guide assembly 46 moves the mover housing 44 along the X axis and about the Z axis and guides the movement of the mover housing 44 along the Y axis. The design of the guide assembly 46 can be varied to suit the design requirements of the device stage assembly 10. In the embodiment illustrated in FIG. 1, the guide assembly 46 is generally rectangular shaped and includes a left guide end 68, and a spaced apart right guide end 70.

The guide assembly 46 also includes a pair of spaced apart, guide fluid pads 72. In this embodiment, each of the guide fluid pads 72 includes a plurality of spaced apart fluid outlets (not shown), and a plurality of spaced apart fluid inlets (not shown). Pressurized fluid (not shown) is released from the fluid outlets towards the stage base 12 and a vacuum is pulled in the fluid inlets to create a vacuum preload type, fluid bearing between each of the guide fluid pads 72 and the stage base 12. The vacuum preload type, fluid bearing maintains the guide assembly 46 spaced apart along the Z axis relative to the stage base 12 and allows for motion of the guide assembly 46 along the X axis, along the Y axis, and about the Z axis relative to the stage base 12.

Additionally, the guide assembly 46 includes a left bracket 74A that extends away from the left guide end 68 and a right bracket 74B that extends away from the right guide end 70. The brackets 74A, 74B secure a portion of the guide movers 48A, 48B, 50 to the guide assembly 46. In the embodiment illustrated in the Figures, each of the brackets 74A, 74B is generally “C” channel shaped.

The guide movers 48A, 48B, 50 and the Y housing mover 52 move the guide assembly 46 and the mover housing 44 relative to the stage base 12. The design of the guide movers 48A, 48B, 50 and the movement of the guide assembly 46 can be varied to suit the movement requirements of the device stage assembly 10. In the embodiment illustrated in FIG. 1, (i) the X guide movers 48A, 48B move the guide assembly 46 and mover housing 44 with a relatively large displacement along the X axis and with a limited range of motion about the Z axis (theta Z), (ii) the Y guide mover 50 moves the guide assembly 46 with a small displacement along the Y axis, and (iii) the Y housing mover 52 moves the mover housing 44 with a relatively large displacement along the Y axis.

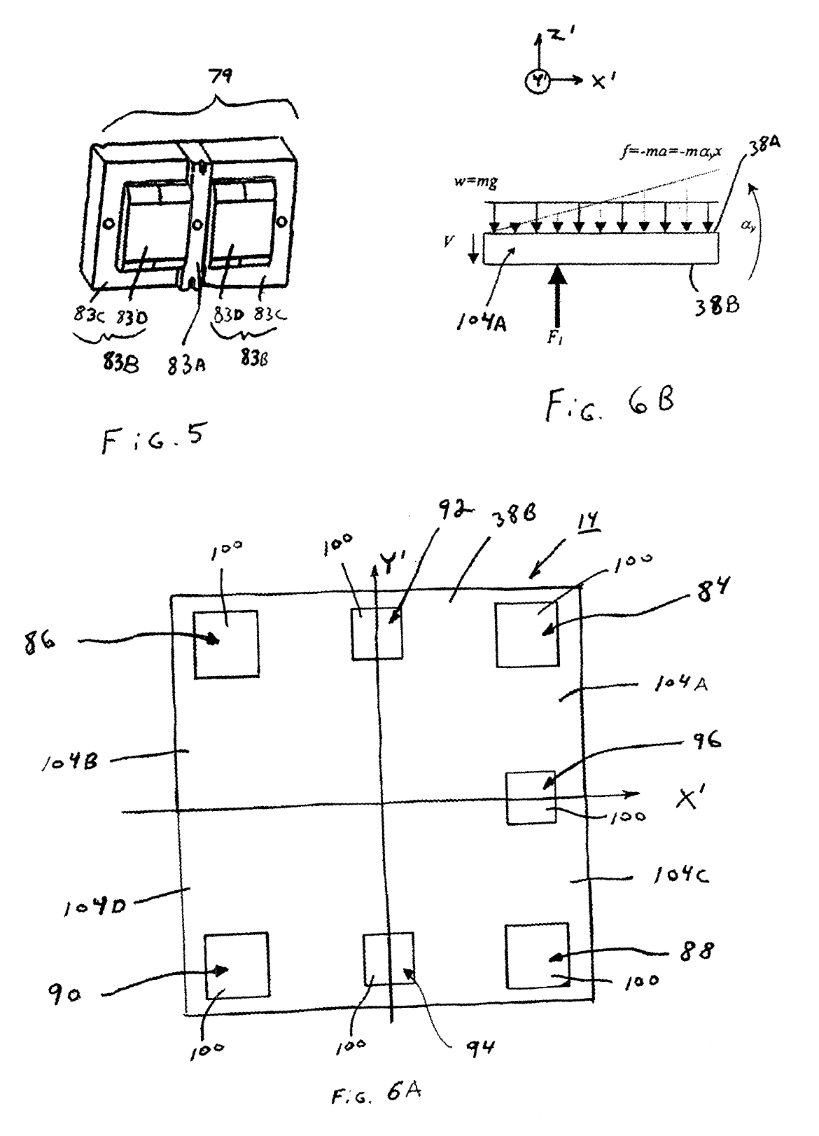

The design of each mover 48A, 48B, 50, 52 can be varied to suit the movement requirements of the device stage assembly 10. For example, each of the movers 48A, 48B, 50, 52 can be a planar motor, rotary motor, voice coil motor, linear motor, electromagnetic actuator, and/or a force actuator. As provided herein, each of the movers 48A, 48B, 50, 52 includes a reaction component 76 and an adjacent moving component 78 that interacts with the reaction component 76. In the embodiments provided herein, the Y guide mover 50 includes an opposed pair of attraction type actuators 79 (illustrated in FIG. 5). Further, in the embodiments provided herein, for the X guide movers 48A, 48B and the Y housing mover 52, one of the components 76, 78 includes one or more magnet arrays and the other component 76, 78 includes one or more conductor arrays.

Each magnet array includes one or more magnets. The number of magnets in each magnet array can be varied to suit the design requirements of the movers 48A, 48B, 52. Each magnet can be made of a permanent magnetic material such as NdFeB. Each conductor array includes one or more conductors. The number of conductors in each conductor array is varied to suit the design requirements of the movers 48A, 48B, 52. Each conductor can be made of metal such as copper or any substance or material responsive to electrical current and capable of creating a magnetic field such as superconductors.

Electrical current (not shown) is supplied to the conductors in each conductor array by the control system 22. For each mover 48A, 48B, 52, the electrical current in the conductors interacts with the magnetic field(s) generated by the one or more of the magnets in the magnet array. This causes a force (Lorentz type force) between the conductors and the magnets that can be used to move the moving component 78 relative to the reaction component 76.

Specifically, the reaction component 76 and the moving component 78 of each X guide mover 48A, 48B interact to selectively move the guide assembly 46 and the mover housing 44 along the X axis and about the Z axis relative to the stage base 12. In the embodiment illustrated herein, each X guide mover 48A, 48B is a commutated, linear motor. The reaction component 76 for the left X guide mover 48A is secured to a left mover mount 80 while the moving component (not shown) of the left X guide mover 48A is secured to the left bracket 74A at the left guide end 68 of the guide assembly 46. Similarly, the reaction component 76 for the right X guide mover 48B is secured to a right mover mount 82 while the moving component 78 of the right X guide mover 48B is secured to the right bracket 74B at the right guide end 70 of the guide assembly 46.

In this embodiment illustrated in FIG. 1, the left mover mount 80 is generally “U” shaped and the right mover mount 82 is generally “L” shaped. Further, the mover mounts 80, 82 are secured to the stage base 12. Alternately, for example, the mover mounts could be secured to a reaction frame (not shown) or a reaction mass assembly (not shown).

Additionally, in the embodiment illustrated in the Figures, the reaction component 76 of each X guide mover 48A, 48B includes a pair of spaced apart magnet arrays while the moving component 78 of each X guide mover 48A, 48B includes a conductor array. Alternately, for example, the reaction component 76 can include a conductor array while the moving component 78 can include a pair of spaced apart magnet arrays.

The required stroke of the X guide movers 48A, 48B along the X axis will vary according to desired use of the device stage assembly 10. For an exposure apparatus 30, generally, the stroke of the X guide movers 48A, 48B for moving the semiconductor wafer 28 is between approximately two hundred (200) millimeters and one thousand (1000) millimeters.

The X guide movers 48A, 48B also make relatively slight adjustments to position of the guide assembly 46 and the mover housing 44 about the Z axis. In order to make the adjustments about the Z axis, the moving component 78 of one of the X guide movers 48A, 48B is moved relative to the moving component 78 of the other X guide mover 48A, 48B. With this design, the X guide movers 48A, 48B generate torque about the Z axis. A gap (not shown) exists between the reaction component 76 and the moving component 78 of each X guide mover 48A, 48B to allow for slight movement of the guide assembly 46 about the Z axis. Typically, the gap is between approximately one millimeter and five millimeters. However, depending upon the design of the particular mover, a larger or smaller gap may be utilized.

The Y guide mover 50 selectively moves the guide assembly 46 along the Y axis relative to the stage base 12. In the embodiment illustrated herein, the Y guide mover 50 includes the opposed pair of the attraction only type actuators 79. FIG. 5 illustrates a perspective view of a preferred pair of attraction type actuators 79. More specifically, FIG. 5 illustrates a perspective view of a pair of spaced E/I core type electromagnetic actuators. The actuator 79 includes an I shaped core 83A and an opposed pair of the combination 83B that includes an E shaped core 83C and a tubular conductor 83D. The E shaped core 83C and the I shaped core 83A are each made of a magnetic material such as iron, silicon steel, or Ni—Fe steel. The conductor 83D is positioned around the center bar of the E shaped core 83C.

For the Y guide mover 50, the moving component 78 is secured to the left bracket 74A and the reaction component 76 is secured to the left mover mount 80. In this embodiment, a pair of the combination 83B is considered the moving component 78 and a row of I cores 83A is considered the reaction component 76.

The Y housing mover 52 moves the mover housing 44 with a relatively large displacement along the Y axis relative to the stage base 12. More specifically, the reaction component 76 (illustrated in phantom in FIG. 1) and the moving component (not shown) of the Y housing mover 52 interact to selectively move the mover housing 44 along the Y axis relative to the guide assembly 46. In the embodiment illustrated herein, the Y housing mover 52 is a commutated, linear motor. The reaction component 76 for the Y housing mover 52 is secured to the guide assembly 46, and the moving component is secured to the mover housing 44, within the guide opening 60. In this embodiment, the reaction component 76 of the Y housing mover 52 includes a conductor array and the moving component of the Y housing mover 52 includes a magnet array. Alternately, for example, the reaction component 76 of the Y housing mover 52 could include a magnet array while the moving component of the Y housing mover 52 could include a conductor array.

With this design, the Y housing mover 52 makes relatively large displacement adjustments to the position of the mover housing 44 along the Y axis. The required stroke of the Y housing mover 52 along the Y axis will vary according to desired use of the device stage assembly 10. For an exposure apparatus 30, generally, the stroke of the Y housing mover 52 for moving the semiconductor wafer 28 is between approximately one hundred (100) millimeters and six hundred (600) millimeters.

The support assembly 18 supports and positions the device stage 14 relative to the mover housing 44 and the stage base 12. The design of the support assembly 18 can be varied to suit the design requirements to the device stage assembly 10. For example, the support assembly 18 can adjust the position of the device stage 14 relative to the mover housing 44 with six degrees of freedom. Alternately, for example, the support assembly 18 can be designed to move the device stage 14 relative to the mover housing 44 with only three degrees of freedom.

In the design illustrated in the Figures, the support assembly 18 moves and supports the device stage 14 with six degrees of freedom. In this embodiment, the support assembly 18 includes (i) a first Z device stage mover 84, (ii) a second Z device stage mover 86, (iii) a third Z device stage mover 88, (iv) a fourth Z device stage mover 90, (v) a first X device stage mover 92, (vi) a second X device stage mover 94, and (vii) a Y device stage mover 96. The device stage movers 84, 86, 88, 90, 92, 94, 96 cooperate to move and position the device stage 14 (i) along the X axis, Y axis and Z axis, and (ii) about the X axis, Y axis and Z axis relative to the mover housing 44 and the stage base 12.

More specifically, the Z device stage movers 84, 86, 88, 90 cooperate to selectively move and support the device stage 14 along the Z axis, about the X axis and about the Y axis. The X device stage movers 92, 94 cooperate to move the device stage 14 along the X axis and about the Z axis. The Y device stage mover 96 moves the device stage 14 along the Y axis. The design of each of the device stage movers 84, 86, 88, 90, 92, 94, 96 can be varied to suit the requirements of the device stage assembly 10. For example, each of the device stage movers 84, 86, 88, 90, 92, 94, 96 can be a voice coil motor, linear motor, and/or force actuator. In the embodiments illustrated herein, each of the device stage movers 84, 86, 88, 90, 92, 94, 96 includes a first component 100 and an adjacent second component 102.

Specifically, the first component 100 and the second component 102 for each of the Z device stage movers 84, 86, 88, 90 interact to selectively move and support the device stage 14 along the Z axis, about the X axis and about the Y axis relative to the mover housing 44 and the stage base 12. In the embodiments provided herein, each of the Z device stage movers 84, 86, 88, 90 is commonly referred to as a voice coil motor. In this design, the first component 100 moves relative to the second component 102 along the Z axis.

In the embodiments provided herein, one of the components 100, 102 of each Z device stage mover 84, 86, 88, 90 includes one or more magnets (not shown) and the other component 100, 102 of each Z device stage mover 84, 86, 88, 90 includes one or more conductors. The size and shape of each conductor and the magnet can be varied to suit the design requirements of each Z device stage mover 84, 86, 88, 90.

As provided herein, electrical current (not shown) is individually supplied to each conductor by the control system 22. For each of the movers 84, 86, 88, 90, the electrical current through the conductors causes the conductors to interact with the magnetic field of the magnets. This generates a force (Lorentz type force) between the magnets and the conductors that can be used to control, move, and position the first component 100 relative to the second component 102 and the device stage 14 relative to the mover housing 44.

In the embodiment illustrated in FIGS. 3 and 4, the first component 100 of each Z device stage mover 84, 86, 88, 90 includes a pair of concentric, tubular shaped magnets and the second component 102 of each Z device stage mover 84, 86, 88, 90 includes a tubular shaped conductor that is positioned between the concentric magnets. With this design, the electrical lines (not shown) carrying current to the conductors are connected to the mover housing 44 and not to the device stage 14.

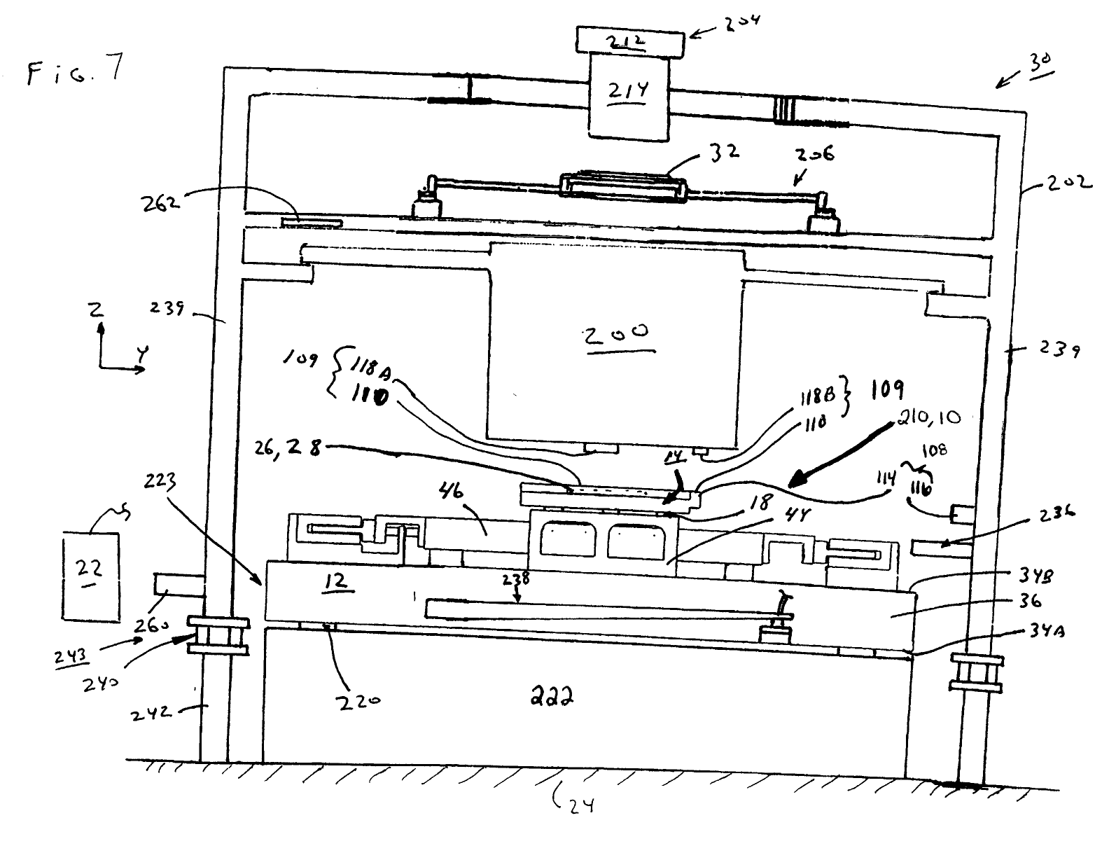

Referring to FIG. 6A, with the use of the four Z movers 84, 86, 88, 90, the device stage 14 is effectively divided into four rectangular shaped sections along the X and Y axes. The sections include a first section 104A, a second section 104B, a third section 104C, and a fourth section 104D. Each of the Z movers 84, 86, 88, 90 is positioned in one of the sections 104A, 104B, 104C, 104D.

Referring back to FIGS. 3 and 4, for the first Z device stage mover 84, the first component 100 is secured to the bottom 38B of the device stage 14 in the first section 104A, while the second component 102 is secured to a front right section 105A of the housing top 54 of the mover housing 44. For the second Z device stage mover 86, the first component 100 is secured to the bottom 38B of the device stage 14 in the second section 104B, while the second component 102 is secured to a rear right section 105B of the housing top 54 of the mover housing 44. For the third Z device stage mover 88, the first component 100 is secured to the bottom 38B of the device stage 14 in the third section 104C, while the second component 102 is secured to a front left section 105C of the housing top 54 of the mover housing 44. For the fourth Z device stage mover 90, the first component 100 is secured to the bottom 38B of the device stage 14 in the fourth section 104D, while the second component 102 is secured to a rear left section 105D of the housing top 54 of the mover housing 44.

The use of four, spaced apart Z device stage movers 84, 86, 88, 90 distributes the forces on the device stage 14 in a way that more closely matches the gravitational and inertial loads on the device stage 14. Uniquely, as provided below, the control system 22 independently controls the Z movers 84, 86, 88, 90 to move and support the device stage 14 while minimizing both static and dynamic deformation of the device stage 14. This improves the positioning performance of the device stage assembly 10. Further, for an exposure apparatus 30, this allows for more accurate positioning of the semiconductor wafer 28 relative to the reticle 32 (illustrated in FIG. 7). Alternately, for example, more than four Z device stage movers can be used to support and move the device stage.

For each of the X device stage movers 92, 94, the first component 100 and the second component 102 interact to selectively move the device stage 14 along the X axis, and about the Z axis relative to the mover housing 44. Somewhat similarly, the first component 100 and the second component 102 of the Y device stage mover 96 interact to selectively move the device stage 14 along the Y axis relative to the mover housing 44. In the embodiments provided herein, each of the X device stage movers 92, 94 and the Y device stage mover 96 includes a pair of the attraction only type actuators 79.

The attraction only type actuators 79 used in the X and Y device stage movers 92, 94, 96 are similar to the actuators 79 illustrated in FIG. 5 and described above. In FIGS. 3 and 4, each of the X and Y device stage movers 92, 94, 96 includes (i) an opposed pair of the combination 83B of the E core 83C and conductor 83D, and (ii) an I core 83A positioned there between.

For each of the X and Y device stage movers 92, 94, 96, the I core 83A is considered the first component 100 and is secured to the bottom 38B of the device stage 14 and the pairs of the combination 83B is considered the second component 102 and is secured to the housing top 54 of the mover housing 44. In the embodiment illustrated in FIGS. 3 and 4, (i) the first X device stage mover 92 is positioned between the first Z device stage mover 84 and the second Z device stage mover 86, (ii) the second X device stage mover 94 is positioned between the third Z device stage mover 88 and the fourth Z device stage mover 90, and (iii) the Y device stage mover 96 is positioned between the first Z device stage mover 84 and the third Z device stage mover 88.

The measurement system 20 monitors movement of the device stage 14 relative to the stage base 12, or to some other reference such as an optical assembly 200 (illustrated in FIG. 7). With this information, the support assembly 18 precisely positions of the device stage 14. The design of the measurement system 20 can be varied. For example, the measurement system 20 can utilize laser interferometers, encoders, and/or other measuring devices to monitor the position of the device stage 14.

In the embodiments provided herein, the measurement system 20 monitors the position of the device stage 14 (i) along the X axis, the Y axis, the Z axis and (ii) about the X axis, the Y axis and the Z axis relative to the optical assembly 200.

In the embodiment illustrated in the Figures, the measurement system 20 includes an X sensor 106, a Y sensor 108, and a Z sensor 109. The X sensor 106 is an interferometer that includes an XZ mirror 110 and an X block 112. The X block 112 interacts with the XZ mirror 110 to monitor the location of the device stage 14 along the X axis and about the Z axis (theta Z). More specifically, the X block 112 generates a pair of spaced apart laser beams (not shown) and detects the beams that are reflected off of the XZ mirror 110. With the information obtained from the beams detected by the X block 112, the location of the device stage 14 along the X axis and about the Z axis can be monitored.

In the embodiment illustrated in the Figures, the XZ mirror 110 is rectangular shaped and extends along one side of the device stage 14. The X block 112 is positioned away from the mover housing 44. The X block 112 can be secured to the apparatus frame 202 (illustrated in FIG. 7) or some other location that is isolated from vibration.

Somewhat similarly, the Y sensor 108 is an interferometer that includes a YZ mirror 114 and a Y block 116. The YZ mirror 114 interacts with the Y block 116 to monitor the position of the device stage 14 along the Y axis. More specifically, the Y block 116 generates a laser beam and detects the beam that is reflected off of the YZ mirror 114. With the information obtained from the beams detected by the Y block 116, the location of the device stage 14 along the Y axis can be monitored.

In the embodiment illustrated in the Figures, the YZ mirror 114 is rectangular shaped and is positioned along one of the sides of the device stage 14. The Y block 116 is positioned away from the device stage 14. The Y block 116 can be secured to the apparatus frame 202 or some other location that is isolated from vibration.

The Z sensor 109 can be implemented as one or more encoders, interferometer, or other sensors (not shown) that measure the Z, theta-X, and theta-Y position of the device stage 14 relative to the mover housing 44. With this implementation, it is necessary to make the mover housing 44 sufficiently rigid that its deformation or vibration does not cause errors in the Z sensor measurement. In addition to, or instead of, these sensors, the Z sensor 109 can include a sensor (such as an auto-focus/auto-leveling sensor) that measures the position and orientation of the device 26 relative to the optical assembly 200. Alternatively, other sensors can be used to measure the Z, theta-X, and theta-Y position of the device stage 14 relative to the mover housing 44 or more preferably the optical assembly 200.

Additionally, as illustrated in FIG. 4, the measurement system 20 can include one or more bending sensors 120 for monitoring bending and deflection of the device stage 14. The design of the bending sensor 120 can be varied to suit the requirements of the device stage 14. The bending sensor 120 can include one or more laser interferometers, encoders, and/or other sensors. In the embodiment illustrated in FIG. 4, the bending sensor 120 includes a sensor arm 122, a table target 124, and a sensor line 126. The sensor arm 122 includes an arm attachment section 128, an arm beam 130, and an arm sensor 132. The arm attachment section 128 secures the sensor arm 122 to one of the sides 40 of the device stage 40. The arm beam 130 cantilevers away from the arm attachment section 128 along the device stage 40. The arm sensor 132 extends downwardly from a distal end of the arm beam 130. The table target 124 is secured to the device stage 14 directly below the arm sensor 132. The sensor line 126 electrically connects the bending sensor 120 to the control system 22.

In this embodiment, the bending sensor 120 monitors bending and deformation of the device stage 14 by monitoring the movement of the arm sensor 132 relative to the table target 124.

The control system 22 controls the stage mover assembly 16 and the support assembly 18 to precisely position the device stage 14 and the device 26. In the embodiment illustrated herein, the control system 22 directs and controls the current to each of the X guide movers 48A, 48B to control movement of the guide assembly 46 along the X axis and about the Z axis. Similarly, the control system 22 directs and controls the current to conductor array of the Y housing mover 52 to control the position of the mover housing 44 along the guide assembly 46 and the conductors 83D of the Y guide mover 50 to control movement of the guide assembly 46 along the Y axis.

Additionally, the control system 22 controls the device stage movers 84, 86, 88, 90, 92, 94, 96 in the support assembly 18 to control the position of the device stage 14 with six degrees of freedom. Importantly, the control system 22 independently controls the Z device stage movers 84, 86, 88, 90 to reduce and minimize both static and dynamic bending and deformation of the device stage 14.

The present invention provides two preferred methods used by the control system 22 to calculate the correct force that each of the Z stage movers 84, 86, 88, 90 should apply on the device stage 14 to produce the desired acceleration and movement of the device stage 14 and to minimize dynamic bending and distortion of the device stage 14. The following symbols are used in conjunction with the discussion provided below to describe the control of the Z stage movers 84, 86, 88, 90 by the control system 22:

F₁ represents the force generated by the first Z device stage mover 84;

F₂ represents the force generated by the second Z device stage mover 86;

F₃ represents the force generated by the third Z device stage mover 88;

F₄ represents the force generated by the fourth Z device stage mover 90;

F_{z} represents the sum of the forces generated by the Z device stage movers 84, 86, 88, 90 on the device stage 14 along the Z axis;

T_{X} represents the sum of the moments (torques) generated by the Z device stage movers 84, 86, 88, 90 on the device stage 14 about the X axis;

T_{Y} represents the sum of the moments (torques) generated by the Z device stage movers 84, 86, 88, 90 on the device stage 14 about the Y axis; and

fg represents the force required to counteract gravity on the device stage 14.

As provided herein, the control system 22 determines the desired force for each of the Z stage movers 84, 86, 88, 90 to move, support and accurately position the device stage 14 along the Z axis, about the X axis (θx), and about the Y axis (θy) while minimizing both static and dynamic bending and deformation of the device stage 14. There are three dynamic equations:

1. the sum of forces along the Z axis;

2. the sum of torques about the X axis (θx); and

3. the sum of torques about the Y axis (θy).

In the prior art, when there were three Z actuators, it is straightforward to solve these equations for the three unknown forces. However, in the present case, there are only three equations and four unknowns, namely F₁, F₂, F₃, F₄. Thus, some additional information is required.

In the first method used by the control system 22, the additional equation is a constraint that ensures the bending and deformation of the device stage 14 is minimized.

The basic problem is to determine the 4-element vector fg and the 4×3 matrix M in this equation:

$$\{ \begin{matrix}{F}_{1} \\ {F}_{2} \\ {F}_{3} \\ {F}_{4}\end{matrix} \} = fg + [ M ] \{ \begin{matrix}{F}_{z} \\ {T}_{x} \\ {T}_{y}\end{matrix} \}$$

If the Z device stage movers 84, 86, 88, 90 do not provide gravity support for the device stage 14, the fg term is zero.

As provided above, FIG. 6A illustrates the bottom 38B of the device stage 14 with the four Z device stage movers 84, 86, 88, 90 spaced apart. The X′ and Y′ axes illustrated in FIG. 6A are assumed to be the principle axes of the device stage 14, and can be different than the X and Y axes in FIGS. 1-4.

FIG. 6B illustrates the forces acting on a side-view of the first section 104A of the device stage 14 when the device stage 14 is undergoing angular acceleration α_{y.} Each of the other sections 104B, 104C, 104D can be analyzed in a similar fashion. Gravity acts as a uniformly distributed load, mg (m is the mass per unit length in X). The acceleration of the first section 104A of the device stage 14 is shown as an inertial force, f=−ma. In this example, the first section 104A of the device stage 14 is accelerating in the θ_{y} direction with angular acceleration α_{y}. At each point of the first section 104A, the linear acceleration, a, is equal to α_{y}x. There is also a shear force, V, applied to the first section 104A by the adjacent sections 104B, 104C, 104D. In this method, the control system 22 uses the algorithm provided below to ensure that the shear force is substantially zero (V=0). This will minimize the bending and deformation of the device stage 14.

When we include the acceleration force, f, then this problem is equivalent to a static problem. Accordingly, we can write the static equilibrium equation for the Z direction:

Σf·\hat{K}=0

In other words, the sum of the Z-components of all of the forces is zero. In this case, this equation becomes

V=∫gdm−∫α_{y}xdm−F₁

Where dm is a differential mass element, and the integrals are performed over the entire first section 104A. Assuming that V=0, solving this equation for F₁ gives

F₁=∫gdm−∫α_{y}xdm

The first term in this equation is simply the gravitational force on the first section 104A, Fg1, which does not change over time. The second term is the force required to create the angular acceleration, α_{y}. Although α_{y} changes with time, it does not change with position. Accordingly, α_{y} can be removed from the integral:

F₁=F_{g1}−α_{y}∫xdm

The same analysis applies in the Y direction for angular acceleration αₓ, and for vertical acceleration α_{z}. When these results are combined, the total equation for F₁ becomes

F₁=F_{g1}−a_{z}∫dm−αₓ∫ydm−α_{y}∫xdm

The three integrals in this equation are constant with time, and can be calculated off-line. We'll call the values of the integrals A_{z1}, A_{y1}, Aₓ₁:

A_{z1}=−∫dm

A_{y1}=−∫ydm

Aₓ₁=−∫xdm

Now the equation for F₁ is

F₁=F_{g1}+A_{z1}a_{z}+A_{y1}αₓ+Aₓ₁α_{y}

The four constants, F_{g1}, Aₓ₁, A_{y1} and A_{z1} are determined by the mass and geometry of the first section 104A of the device stage 14. Similar equations can be derived for the other three Z device stage movers 86, 88, 90:

F₁=F_{g1}+A_{z1}a_{z}+A_{y1}αₓ+Aₓ₁α_{y}

F₂=F_{g2}+A_{z2}a_{z}+A_{y2}αₓ+Aₓ₂α_{y}

F₃=F_{g3}+A_{z3}a_{z}+A_{y3}αₓ+Aₓ₃α_{y}

F₄=F_{g4}+A_{z4}a_{z}+A_{y4}αₓ+Aₓ₄α_{y}

Putting this equation into matrix form, results in the following equation:

$$\{ \begin{matrix}{F}_{1} \\ {F}_{2} \\ {F}_{3} \\ {F}_{4}\end{matrix} \} = {f}_{g} + [ \begin{matrix}{A}_{z1} & {A}_{y1} & {A}_{x1} \\ {A}_{z2} & {A}_{y2} & {A}_{x2} \\ {A}_{z3} & {A}_{y3} & {A}_{x3} \\ {A}_{z4} & {A}_{y4} & {A}_{x4}\end{matrix} ] \{ \begin{matrix}{a}_{z} \\ {α}_{x} \\ {α}_{y}\end{matrix} \}$$

From this equation, the matrix M is

$$- [ \begin{matrix}{}_{1} \int ⅆ m & {}_{1} \int y ⅆ m & {}_{1} \int x ⅆ m \\ {}_{2} \int ⅆ m & {}_{2} \int y ⅆ m & {-}_{2} \int x ⅆ m \\ {}_{3} \int ⅆ m & {-}_{3} \int y ⅆ m & {-}_{3} \int x ⅆ m \\ {}_{4} \int ⅆ m & {-}_{4} \int y ⅆ m & {}_{4} \int x ⅆ m\end{matrix} ]$$

The subscripts under the integral sign indicate the specific section 104A, 104B, 104C, 104D of the device stage 14. In this method, each a_{z}, αₓ and α_{y} can be set as information that is used to calculate each desired force F₁, F₂, F₃, and F₄ in each corresponding control (such as servo control). Each a_{z}, αₓ and α_{y} can be obtained from three signals from the Z sensor 109 shown in FIG. 7.

A second method used by the control system 22 for controlling the device stage 14 with the four Z device stage movers 84, 86, 88, 90 uses the bending sensor 120 illustrated in FIG. 4 to monitor the bending and deformation of the device stage 14. Using the information from the bending sensor 120, and the three signals from the Z sensor 109 provides a total of four sensor signals that can be used by the control system 22 to control the four Z stage movers 84, 86, 88, 90. Using a finite-element model, experiments, or another means, it is possible to determine a matrix, M, which relates displacements measured by the bending sensor 120 and the Z sensor 109 to the forces produced by the four Z device stage movers 84, 86, 88, 90.

$$\{ \begin{matrix}Z \\ {Θ}_{x} \\ {Θ}_{y} \\ \partial \end{matrix} \} = [ M ] \{ \begin{matrix}{F}_{1} \\ {F}_{2} \\ {F}_{3} \\ {F}_{4}\end{matrix} \}$$

Where Z, ⊖ₓ, ⊖_{y}, are the output measured by the Z sensor 109 and ∂ is the output measured by the bending sensor 120 (3 position sensors and 1 bending sensor). Once this matrix, M, is known, its inverse can be used in a control law as shown in this equation:

$$\{ \begin{matrix}{F}_{1} \\ {F}_{2} \\ {F}_{3} \\ {F}_{4}\end{matrix} \} = {G ( s ) [ M ]}^{- 1} \{ \begin{matrix}Z \\ {Θ}_{x} \\ {Θ}_{y} \\ \partial \end{matrix} \}$$

Here the function G(s) represents a compensator of the control system 22, and the vector Z, ⊖ₓ, ⊖_{y}, and ∂ is the measured error of each sensor value. To avoid ambiguous bending measurements, the system can be operated in a range where δ does not cross zero.

The second method could be used by the control system 22 with designs that include more than four Z device stage movers by adding additional bending sensors 120. The basic idea is to ensure that the total number of sensors equals the number of Z device stage movers.

FIG. 7 is a schematic view illustrating an exposure apparatus 30 useful with the present invention. The exposure apparatus 30 includes the apparatus frame 202, an illumination system 204 (irradiation apparatus), a reticle stage assembly 206, the optical assembly 200 (lens assembly), and a wafer stage assembly 210. The device stage assemblies 10 provided herein can be used as the wafer stage assembly 210. Alternately, with the disclosure provided herein, the device stage assemblies 10 provided herein can be modified for use as the reticle stage assembly 206.

The exposure apparatus 30 is particularly useful as a lithographic device that transfers a pattern (not shown) of an integrated circuit from the reticle 32 onto the semiconductor wafer 28. The exposure apparatus 30 mounts to the mounting base 24, e.g., the ground, a base, or floor or some other supporting structure.

Preferably, referring to FIGS. 7 and 8A, the stage base 12 is secured with a base support assembly 220 and a base frame 222 to the mounting base 24. The combination of the stage base 12, the base support assembly 220, and the base frame 222 is referred to herein as a base stage assembly 223. The base support assembly 220 reduces the effect of vibration of the base frame 222 causing vibration on the stage base 12. Further, the base support assembly 220 supports and positions the stage base 12 relative to the base frame 222 and the mounting base 24.

The design of the base support assembly 220 can be varied to suit the design requirements of the device stage assembly 10. In the design illustrated in FIGS. 7 and 8A, the base support assembly 220 moves and supports the stage base 12 with three degrees of freedom. Referring to FIG. 8A, in this embodiment, the base support assembly 220 includes (i) a first Z base mover 224, (ii) a second Z base mover 226, (iii) a third Z base mover 228, and (iv) a fourth Z base mover 230. It should be noted in the embodiment illustrated in FIG. 8A, the base support assembly 220 can support or adjust the position of the stage base 12 along the X axis, along the Y axis, and about the Z axis by passive systems (not shown) or additional actuators (not shown).

The Z base movers 224, 226, 228, 230 cooperate to adjust the position of the stage base 12 relative to the mounting base 24 along the Z axis and about the X axis and the Y axis. The design of each of the Z base movers 224, 226, 228, 230, can be varied. For example, each of the Z base movers 224, 226, 228, 230 can be a planar motor, voice coil motor, linear motor, electromagnetic actuator, and/or force actuator. In the embodiment illustrated herein, the design of each of the Z base movers 224, 226, 228, 230 is substantially similar as the design of the Z device stage movers 84, 86, 88, 90, described above.

Referring to FIG. 8A, each of the Z base movers 224, 226, 228, 230 include a first component 232 and a second component 234. Specifically, the first component 232 and the second component 234 for each of the Z base movers 224, 226, 228, 230 interact to selectively move the stage base 12 along the Z axis, about the X axis and about the Y axis relative to the base frame 222. In the embodiments provided herein, each of the Z base movers 224, 226, 228, 230 is commonly referred to as a voice coil motor. In the design provided herein, the first component 232 moves relative to the second component 234 along the Z axis, about the X axis and about the Y axis.

In the embodiments provided herein, one of the components 232, 234 of each Z base movers 224, 226, 228, 230 includes one or more magnets (not shown) and the other component 232, 234 of each Z base mover 224, 226, 228, 230 includes one or more conductors. The size and shape of each conductor and the magnet can be varied to suit the design requirements of each Z base mover 224, 226, 228, 230.

As provided herein, electrical current (not shown) is individually supplied to each conductor by the control system 22. For each of the movers 224, 226, 228, 230, the electrical current through the conductors causes the conductors to interact with the magnetic field of the magnets. This generates a force (Lorentz type force) between the magnets and the conductors that can be used to control, move, and position the first component 232 relative to the second component 234.

Referring to FIGS. 7 and 8A, the base stage assembly 223 also includes a Z base sensor 236 and a base bending sensor 238. The Z base sensor 236 monitors the position of the stage base 12 along the Z axis, about the X axis, and about the Y axis. The base bending sensor 238 monitors bending of the stage base 12. The design of the Z base sensor 236 and the base bending sensor 238 can be similar to the corresponding components described above.

Importantly, with this design, the control system 22 independently controls the Z base movers 224, 226, 228, 230 to reduce and minimize both static and dynamic bending and deformation of the stage base 12. The methods described above for controlling the Z device stage movers 84, 86, 88, 90 can be utilized for controlling the Z base movers 224, 226, 228, 230.

The apparatus frame 202 is rigid and supports some of the components of the exposure apparatus 30. The design of the apparatus frame 202 can be varied to suit the design requirements for the rest of the exposure apparatus 30. The apparatus frame 202 illustrated in FIG. 7 supports the optical assembly 200 and the illumination system 204 and the reticle stage assembly 206 above the mounting base 24.

Preferably, referring to FIGS. 7 and 8B, the apparatus frame 202 includes four side beams 239 and is secured with a frame support assembly 240 and a frame base 242 to the mounting base 24. The combination of the apparatus frame 202, the frame support assembly 240 and the frame base 242 is referred to herein as a frame stage assembly 243. The frame support assembly 240 reduces the effect of vibration of the frame base 242 causing vibration on the apparatus frame 202. Further, the frame support assembly 240 supports and positions the apparatus frame 202 relative to the mounting base 24.

The design of the frame support assembly 240 can be varied to suit the design requirements of the device stage assembly 10. In the design illustrated in FIGS. 7 and 8B, the frame support assembly 240 moves and supports the apparatus frame 202 with three degrees of freedom. In this embodiment, the frame support assembly 240 includes (i) a first Z frame mover 244, (ii) a second Z frame mover 246, (iii) a third Z frame mover 248, (iv) a fourth Z frame mover 250, (v) a first resilient supporter 252, (vi) a second resilient supporter 254, (vii) a third resilient supporter 256, and (viii) a fourth resilient supporter 258.

The Z frame movers 244, 246, 248, 250 cooperate to adjust the position of the apparatus frame 202 relative to the mounting base 24 along the Z axis and about the X axis and the Y axis. The design of each of the Z frame movers 244, 246, 248, 250 can be varied. For example, each of the Z frame movers 244, 246, 248, 250 can be a planar motor, rotary motor, voice coil motor, linear motor, electromagnetic actuator, piezoelectric actuator, and/or force actuator. The design of each of the Z frame movers 244, 246, 248, 250 can be substantially similar as the design of the Z device stage movers 84, 86, 88, 90 described above.

Referring to FIG. 7, the frame stage assembly 243 also includes a Z frame sensor 260 and a frame bending sensor 262. The Z frame sensor 260 monitors the position of the apparatus frame 202 along the Z axis, about the X axis, and about the Y axis. The frame bending sensor 262 monitors bending of the apparatus frame 202. The design of the Z frame sensor 260 and the frame bending sensor 262 can be similar to the corresponding components described above.

Importantly, with this design, the control system 22 independently controls the Z frame movers 244, 246, 248, 250 to reduce and minimize both static and dynamic deformation of the apparatus frame 202. The methods described above for controlling the Z device stage movers 84, 86, 88, 90 can be utilized for controlling the Z frame movers 244, 246, 248, 250.

As provided herein, the resilient supporters 252, 254, 256, 258 are positioned between the frame base 242 and the side beams 239. The resilient supporters 252, 254, 256, 258 reduce the effect of vibration of the mounting base 24 causing vibration on the apparatus frame 202. Each of the base resilient supporters 252, 254, 256, 258 for example, can include a pneumatic cylinder or a spring.

The illumination system 204 includes an illumination source 212 and an illumination optical assembly 214. The illumination source 212 emits a beam (irradiation) of light energy that is allowed through the clear areas in the reticle. The illumination optical assembly 214 guides the beam of light energy from the illumination source 212 to the optical assembly 200. The beam illuminates selectively different portions of the reticle 32 and exposes the semiconductor wafer 28. In FIG. 7, the illumination source 212 is illustrated as being supported above the reticle stage assembly 206. Typically, however, the illumination source 212 is secured to one of the sides of the apparatus frame 202 and the energy beam from the illumination source 212 is directed to above the reticle stage assembly 206 with the illumination optical assembly 214.

The optical assembly 200 projects and/or focuses the light passing through the reticle onto the wafer. Depending upon the design of the exposure apparatus 30, the optical assembly 200 can magnify or reduce the image illuminated on the reticle.

The reticle stage assembly 206 holds and positions the reticle relative to the optical assembly 200 and the wafer. Similarly, the wafer stage assembly 210 holds and positions the wafer with respect to the projected image of the illuminated portions of the reticle in the operational area. In FIG. 7, the wafer stage assembly 210 utilizes a device stage assembly 10 having features of the present invention. Depending upon the design, the exposure apparatus 30 can also include additional motors to move the stage assemblies 206, 210.

Further, the present invention can be applied to the reticle stage assembly 206. For example, in the case that reticle stage assembly 206 moves the reticle 32 in the z direction, the reticle stage assembly 206 can include a Z mover and utilize the device stage assembly 10 in the same way to the wafer stage assembly 210.

There are a number of different types of lithographic devices. For example, the exposure apparatus 30 can be used as a scanning type photolithography system that exposes the pattern from the reticle onto the wafer with the reticle and the wafer moving synchronously. In a scanning type lithographic device, the reticle is moved perpendicular to an optical axis of the optical assembly 200 by the reticle stage assembly 206 and the wafer is moved perpendicular to an optical axis of the optical assembly 200 by the wafer stage assembly 210. Scanning of the reticle and the wafer occurs while the reticle and the wafer are moving synchronously.

Alternately, the exposure apparatus 30 can be a step-and-repeat type photolithography system that exposes the reticle while the reticle and the wafer are stationary. In the step and repeat process, the wafer is in a constant position relative to the reticle and the optical assembly 200 during the exposure of an individual field. Subsequently, between consecutive exposure steps, the wafer is consecutively moved by the wafer stage perpendicular to the optical axis of the optical assembly 200 so that the next field of the wafer is brought into position relative to the optical assembly 200 and the reticle for exposure. Following this process, the images on the reticle are sequentially exposed onto the fields of the wafer so that the next field of the wafer is brought into position relative to the optical assembly 200 and the reticle.

However, the use of the exposure apparatus 30 and the device stage assembly 10 provided herein are not limited to a photolithography system for semiconductor manufacturing. The exposure apparatus 30, for example, can be used as an LCD photolithography system that exposes a liquid crystal display device pattern onto a rectangular glass plate or a photolithography system for manufacturing a thin film magnetic head. Further, the present invention can also be applied to a proximity photolithography system that exposes a mask pattern by closely locating a mask and a substrate without the use of a lens assembly. Additionally, the present invention provided herein can be used in other devices, including other semiconductor processing equipment, elevators, electric razors, machine tools, metal cutting machines, inspection machines and disk drives.

The illumination source 212 can be g-line (436 nm), i-line (365 nm), KrF excimer laser (248 nm), ArF excimer laser (193 nm) and F₂ laser (157 nm). Alternately, the illumination source 212 can also use charged particle beams such as an x-ray and electron beam. For instance, in the case where an electron beam is used, thermionic emission type lanthanum hexaboride (LaB₆) or tantalum (Ta) can be used as an electron gun. Furthermore, in the case where an electron beam is used, the structure could be such that either a mask is used or a pattern can be directly formed on a substrate without the use of a mask.

In terms of the magnification of the optical assembly 200 included in the photolithography system, the optical assembly 200 need not be limited to a reduction system. It could also be a 1× or magnification system.

With respect to a optical assembly 200, when far ultra-violet rays such as the excimer laser is used, glass materials such as quartz and fluorite that transmit far ultra-violet rays is preferable to be used. When the F₂ type laser or x-ray is used, the optical assembly 200 should preferably be either catadioptric or refractive (a reticle should also preferably be a reflective type), and when an electron beam is used, electron optics should preferably consist of electron lenses and deflectors. The optical path for the electron beams should be in a vacuum.

Also, with an exposure device that employs vacuum ultra-violet radiation (VUV) of wavelength 200 nm or lower, use of the catadioptric type optical system can be considered. Examples of the catadioptric type of optical system include the disclosure Japan Patent Application Disclosure No.8-171054 published in the Official Gazette for Laid-Open Patent Applications and its counterpart U.S. Pat. No. 5,668,672, as well as Japan Patent Application Disclosure No.10-20195 and its counterpart U.S. Pat. No. 5,835,275. In these cases, the reflecting optical device can be a catadioptric optical system incorporating a beam splitter and concave mirror. Japan Patent Application Disclosure No.8-334695 published in the Official Gazette for Laid-Open Patent Applications and its counterpart U.S. Pat. No. 5,689,377 as well as Japan Patent Application Disclosure No.10-3039 and its counterpart U.S. patent application Ser. No. 873,605 (Application Date: Jun. 12, 1997) also use a reflecting-refracting type of optical system incorporating a concave mirror, etc., but without a beam splitter, and can also be employed with this invention. As far as is permitted, the disclosures in the above-mentioned U.S. patents, as well as the Japan patent applications published in the Official Gazette for Laid-Open Patent Applications are incorporated herein by reference.

Further, in photolithography systems, when linear motors (see U.S. Pat. Nos. 5,623,853 or 5,528,118) are used in a wafer stage or a mask stage, the linear motors can be either an air levitation type employing air bearings or a magnetic levitation type using Lorentz force or reactance force. Additionally, the stage could move along a guide, or it could be a guideless type stage that uses no guide. As far as is permitted, the disclosures in U.S. Pat. Nos. 5,623,853 and 5,528,118 are incorporated herein by reference.

Alternatively, one of the stages could be driven by a planar motor, which drives the stage by an electromagnetic force generated by a magnet unit having two-dimensionally arranged magnets and an armature coil unit having two-dimensionally arranged coils in facing positions. With this type of driving system, either the magnet unit or the armature coil unit is connected to the stage and the other unit is mounted on the moving plane side of the stage.

Movement of the stages as described above generates reaction forces that can affect performance of the photolithography system. Reaction forces generated by the wafer (substrate) stage motion can be mechanically released to the floor (ground) by use of a frame member as described in U.S. Pat. No. 5,528,118 and published Japanese Patent Application Disclosure No. 8-136475. Additionally, reaction forces generated by the reticle (mask) stage motion can be mechanically released to the floor (ground) by use of a frame member as described in U.S. Pat. No. 5,874,820 and published Japanese Patent Application Disclosure No. 8-330224. As far as is permitted, the disclosures in U.S. Pat. Nos. 5,528,118 and 5,874,820 and Japanese Patent Application Disclosure No. 8-330224 are incorporated herein by reference.

As described above, a photolithography system according to the above described embodiments can be built by assembling various subsystems, including each element listed in the appended claims, in such a manner that prescribed mechanical accuracy, electrical accuracy, and optical accuracy are maintained. In order to maintain the various accuracies, prior to and following assembly, every optical system is adjusted to achieve its optical accuracy. Similarly, every mechanical system and every electrical system are adjusted to achieve their respective mechanical and electrical accuracies. The process of assembling each subsystem into a photolithography system includes mechanical interfaces, electrical circuit wiring connections and air pressure plumbing connections between each subsystem. Needless to say, there is also a process where each subsystem is assembled prior to assembling a photolithography system from the various subsystems. Once a photolithography system is assembled using the various subsystems, a total adjustment is performed to make sure that accuracy is maintained in the complete photolithography system. Additionally, it is desirable to manufacture an exposure system in a clean room where the temperature and cleanliness are controlled.

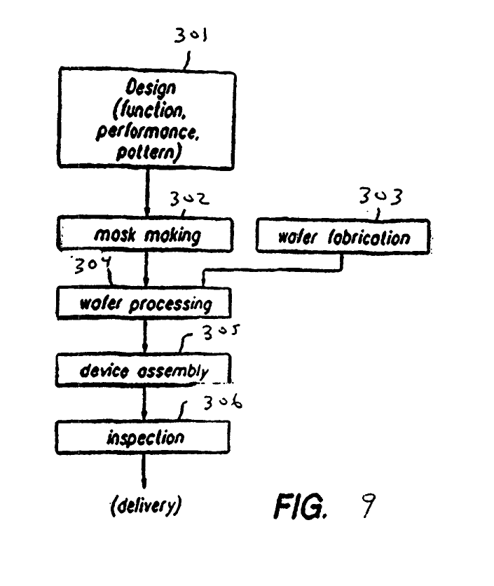

Further, semiconductor devices can be fabricated using the above described systems, by the process shown generally in FIG. 9. In step 301 the device's function and performance characteristics are designed. Next, in step 302, a mask (reticle) having a pattern is designed according to the previous designing step, and in a parallel step 303 a wafer is made from a silicon material. The mask pattern designed in step 302 is exposed onto the wafer from step 303 in step 304 by a photolithography system described hereinabove in accordance with the present invention. In step 305 the semiconductor device is assembled (including the dicing process, bonding process and packaging process), finally, the device is then inspected in step 306.

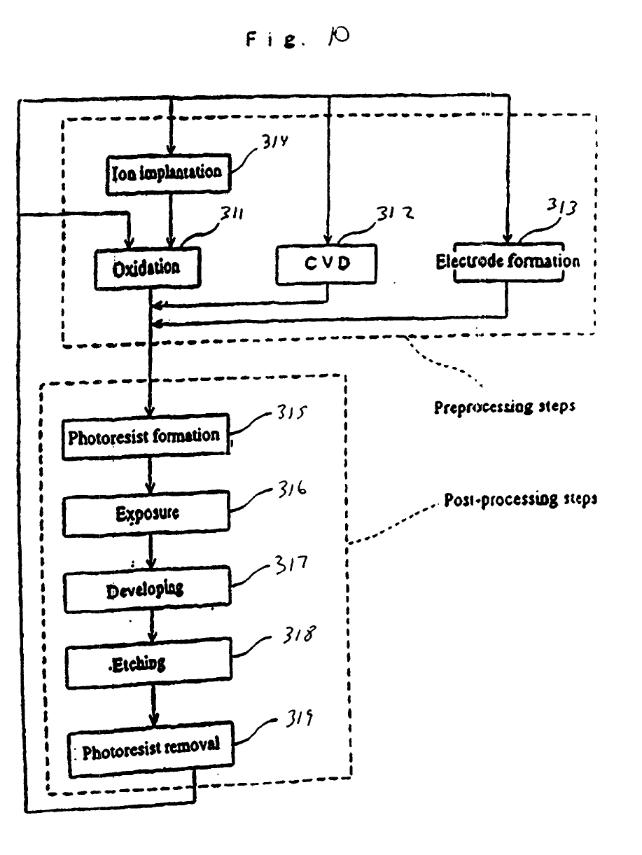

FIG. 10 illustrates a detailed flowchart example of the above-mentioned step 304 in the case of fabricating semiconductor devices. In FIG. 10, in step 311 (oxidation step), the wafer surface is oxidized. In step 312 (CVD step), an insulation film is formed on the wafer surface. In step 313 (electrode formation step), electrodes are formed on the wafer by vapor deposition. In step 314 (ion implantation step), ions are implanted in the wafer. The above mentioned steps 311-314 form the preprocessing steps for wafers during wafer processing, and selection is made at each step according to processing requirements.

At each stage of wafer processing, when the above-mentioned preprocessing steps have been completed, the following post-processing steps are implemented. During post-processing, first, in step 315 (photoresist formation step), photoresist is applied to a wafer. Next, in step 316 (exposure step), the above-mentioned exposure device is used to transfer the circuit pattern of a mask (reticle) to a wafer. Then in step 317 (developing step), the exposed wafer is developed, and in step 318 (etching step), parts other than residual photoresist (exposed material surface) are removed by etching. In step 319 (photoresist removal step), unnecessary photoresist remaining after etching is removed.

Multiple circuit patterns are formed by repetition of these preprocessing and post-processing steps.

While the particular device stage assembly 10 as shown and disclosed herein is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A device stage assembly that moves a device relative to a mounting base, the device stage assembly comprising:
a device stage that retains the device;
a mover housing;
a support assembly that moves the device stage relative to the mover housing, the support assembly including at least four, spaced apart Z device stage movers that are connected to the device stage; and
a control system that controls the Z device stage movers to inhibit deformation of the device stage during movement of the device stage by the Z device stage movers.

2. The device stage assembly of claim I wherein the control system controls the Z device stage movers to inhibit dynamic deformation of the device stage during movement of the device stage by the Z device stage movers.

3. The device stage assembly of claim 1 wherein the control system controls the Z device stage movers to minimize static deformation of the device stage.

4. The device stage assembly of claim 1 wherein the control system controls the Z device stage movers to adjust the position of the device stage relative to the mover housing along a Z axis.

5. The device stage assembly of claim 1 wherein the control system controls the Z device stage movers to adjust the position of the device stage relative to the mover housing along a Z axis, about a X axis, and about a Y axis.

6. The device stage assembly of claim 5 wherein the support assembly includes an X device stage mover that is controlled by the control system to move the device stage relative to the mover housing along an X axis.

7. The device stage assembly of claim 5 wherein the support assembly includes a first X device stage mover, a second X device stage mover and a Y device stage mover that are controlled by the control system to move the device stage relative to the mover housing along the X axis, along the Y axis, and about the Z axis.

8. The device stage assembly of claim 1 further comprising a bending sensor that monitors the bending of the device stage.

9. The device stage assembly of claim 8 wherein the control system controls the Z device stage movers to minimize the bending measured by the bending sensor.

10. The device stage assembly of claim 1 including a stage mover assembly connected to the mover housing, the stage mover assembly moving the mover housing with at least one degree of freedom relative to the mounting base.

11. An exposure apparatus including the device stage assembly of claim 1.

12. The exposure apparatus of claim 11 further comprising (i) a stage base that supports the mover housing, and (ii) a base support assembly that moves the stage base relative to the mounting base, the base support assembly including at least four, spaced apart Z base movers that move the stage base relative to the mounting base and wherein the control system controls the Z base movers to inhibit bending of the stage base during movement of the base stage by the Z base movers.

13. The exposure apparatus of claim 12 including a base bending sensor that monitors the bending of the stage base.

14. The exposure apparatus of claim 11 further comprising (i) an apparatus frame that supports a portion of the device stage assembly above the mounting base, and (ii) a frame support assembly that moves the apparatus frame relative to the mounting base, the frame support assembly including at least four, spaced apart Z frame movers that move the apparatus frame relative to the mounting base and wherein the control system controls the Z frame movers to inhibit bending of the apparatus frame during movement of the apparatus frame by the Z frame movers.

15. The exposure apparatus of claim 14 including a frame bending sensor that monitors the bending of the apparatus frame.

16. A device manufactured with the exposure apparatus according to claim 11.

17. A wafer on which an image has been formed by the exposure apparatus of claim 11.

18. A support assembly that supports and moves a stage relative to a mounting base, the support assembly comprising:
a plurality of spaced apart Z stage movers that are connected to the stage; and
a control system that controls the Z stage movers to move the stage while inhibiting dynamic bending of the stage during movement of the stage by the Z stage movers.

19. The support assembly of claim 18 including at least four spaced apart Z stage movers.

20. The support assembly of claim 18 further comprising a bending sensor that monitors bending of the stage.

21. The support assembly of claim 19 wherein the control system controls the Z stage movers to minimize the bending measured by the bending sensor.

22. The support assembly of claim 18 wherein the Z stage movers are controlled by the control system to move the stage along a Z axis, about a X axis, and about a Y axis.

23. The support assembly of claim 22 further comprising a first X stage mover, a second X stage mover and a Y stage mover that are controlled by the control system to move the stage along the X axis, along the Y axis, and about the Z axis.

24. The device stage assembly for mounting a device, the device stage assembly including the support assembly of claim 18, and a stage that retains the device.

25. An exposure apparatus including the device stage assembly of claim 24.

26. A device manufactured with the exposure apparatus according to claim 25.

27. A wafer on which an image has been formed by the exposure apparatus of claim 25.

28. A base stage assembly including a stage base and the support assembly of claim 18 connected to the stage base.

29. The base stage assembly of claim 28 including a base bending sensor that monitors the bending of the stage base.

30. A frame stage assembly including an apparatus frame and the support assembly of claim 18 connected to the apparatus frame.

31. The frame stage assembly of claim 30 further comprising a frame bending sensor that monitors the bending of the apparatus frame.

32. A method for making a device stage assembly that moves a device relative to a stage base, the method comprising the steps of:
providing a device stage that retains the device;
providing a mover housing;
connecting a support assembly between the device stage and the mover housing, the support assembly including a plurality of spaced apart Z device stage movers that move the device stage relative to the mover housing; and
connecting a controller with the plurality of spaced apart Z device stage movers, the controller controlling the Z device stage movers to inhibit dynamic bending of the device stage during movement of the device stage by the Z device stage movers.

33. The method of claim 32 wherein the step of connecting a support assembly including providing a support assembly that includes at least four spaced apart Z device stage movers.

34. The method of claim 32 wherein the control system controls at least one of the Z device stage movers to adjust the position of the device stage relative to the mover housing along a Z axis, about a X axis, and about a Y axis.

35. The method of claim 32 further comprising the steps of connecting a bending sensor with the control system, the bending sensor monitoring the bending of the device stage.

36. The method of claim 35 wherein the control system controls at least one of the Z device stage movers to minimize the bending measured by the bending sensor.

37. The method of claim 32 including the step of connecting a first X device stage mover, a second X device stage mover and a Y device stage mover to the device stage, the X device stage movers and the Y device stage mover being controlled by the control system to move the device stage relative to the mover housing along an X axis, along a Y axis and about a Z axis.

38. A method for making an exposure apparatus that forms an image on a wafer, the method comprising the steps of:
providing an irradiation apparatus that irradiates the wafer with radiation to form the image on the wafer; and
providing the device stage assembly made by the method of claim 32.

39. A method of making a wafer utilizing the exposure apparatus made by the method of claim 38.

40. A method of making a device including at least the exposure process, wherein the exposure process utilizes the exposure apparatus made by the method of claim 38.

41. A method for driving a stage assembly that moves a stage relative to a base member, the method comprising the steps of:
determining a driving force that inhibits deformation of the stage during movement of the stage; and
providing the driving force to the stage to cause the movement of the stage.
